(19) United States
(12) Patent Application Publication
(10) Pub. No.: US 2013/0279092 A1
(43) Pub. Date: Oct. 24, 2013

(54) CASING STRUCTURE AND ELECTRONIC DEVICE

(71) Applicant: ASUSTEK COMPUTER INC., Taipei (TW)

(72) Inventors: Ting-Hui YAO, Taipei (TW); Yu-Kang LIN, Taipei (TW); Kai-Min HUANG, Taipei (TW); Yen-Chung CHEN, Taipei (TW)

(73) Assignee: ASUSTeK COMPUTER INC., Taipei (TW)

(21) Appl. No.: 13/841,456

(22) Filed: Mar. 15, 2013

Related U.S. Application Data
(60) Provisional application No. 61/635,405, filed on Apr. 19, 2012.

(51) Int. Cl. H05K 5/02; H05K 5/03

(52) U.S. Cl. CPC H05K 5/0221; H05K 5/03
USPC 361/679.01; 312/223.1

(57) ABSTRACT

A casing structure and an electronic device with the casing structure are disclosed. The casing structure includes a first casing, a second casing, a fixing element and a locking element. The second casing has a turning portion and an opening. The opening is formed at the turning portion. The fixing element is disposed in the first casing and corresponds to the opening. The locking element has an end part and a fixing part. The fixing part passes through the opening along a normal line direction of the opening to fix on the fixing element, so as to make the second casing connected to the first casing, and make the end part aligned to the second casing.

### CROSS-REFERENCE TO RELATED APPLICATION

The non-provisional patent application claims priority to U.S. provisional patent application with Ser. No. 61/635,405, filed on Apr. 19, 2012. The entirety of the above-mentioned patent application is hereby incorporated by reference herein and made a part of specification.

### BACKGROUND OF THE INVENTION

1. Field of the Invention

The invention relates to a casing structure and an electronic device and, more particularly, to a casing structure and an electronic device with an integrated appearance.

2. Description of the Related Art

As the development of science technology, an electronic device, such as a notebook computer, an ultrabook computer, a tablet computer, a personal digital assistant (PDA), a global positioning system (GPS), an E-book, an E-dictionary, a game player or a mobile communication device, has powerful functions to meet different requirements of users.

As shown in FIG. 1, screw holes H at a bottom casing 11 of a conventional electronic device 1 are in vertical direction. Thus, fixing elements or connecting elements of the electronic device 1 should be vertical correspondingly, and when screws S are locked to the corresponding screw holes H, they go deep into the casing 11, which looks like broken holes at the casing 11 and makes the casing 11 of the electronic device 1 lack of integrity.

### BRIEF SUMMARY OF THE INVENTION

A casing structure includes a first casing, a second casing, a fixing element and a locking element. The second casing has a turning portion and an opening which is formed at the turning portion. The fixing element is disposed in the first casing and corresponds to the opening. The locking element has an end part and a fixing part. The fixing part passes through the opening along a normal line direction of the opening to fix on the fixing element, so as to make the second casing connected to the first casing, and make the end part aligned to the second casing.

An electronic device includes a casing structure and an electronic device body. The casing structure includes a first casing, a second casing, a fixing element and a locking element. The second casing has a turning portion and an opening which is formed at the turning portion. The fixing element is disposed in the first casing and corresponds to the opening. The locking element has an end part and a fixing part. The fixing part passes through the opening along a normal line direction of the opening to fix on the fixing element, so as to make the second casing connected to the first casing and accommodate the electronic device body, and make the end part aligned to the second casing.

As stated above, in the casing structure and the electronic device, the second casing has the turning portion and the opening which is formed at the turning portion, and the fixing element is disposed at the first casing and corresponds to the opening. The fixing part of the locking element passes through the opening along the normal line direction of the opening to fix on the fixing element, so as to make the second casing of the casing structure connected to the first casing and accommodate the electronic device body, and make the end part aligned to the second casing. Thus, the appearance of the electronic device is integrated.

These and other features, aspects and advantages of the present invention will become better understood with regard to the following description, appended claims, and accompanying drawings.

### BRIEF DESCRIPTION OF THE DRAWINGS

FIG. 1 is a schematic diagram showing a conventional electronic device;

FIG. 2A is a bottom view showing an electronic device in an embodiment;

FIG. 2B and FIG. 2C are partial schematic diagrams showing the electronic device in FIG. 2A; and

FIG. 2D is a sectional diagram showing the electronic device in FIG. 2C.

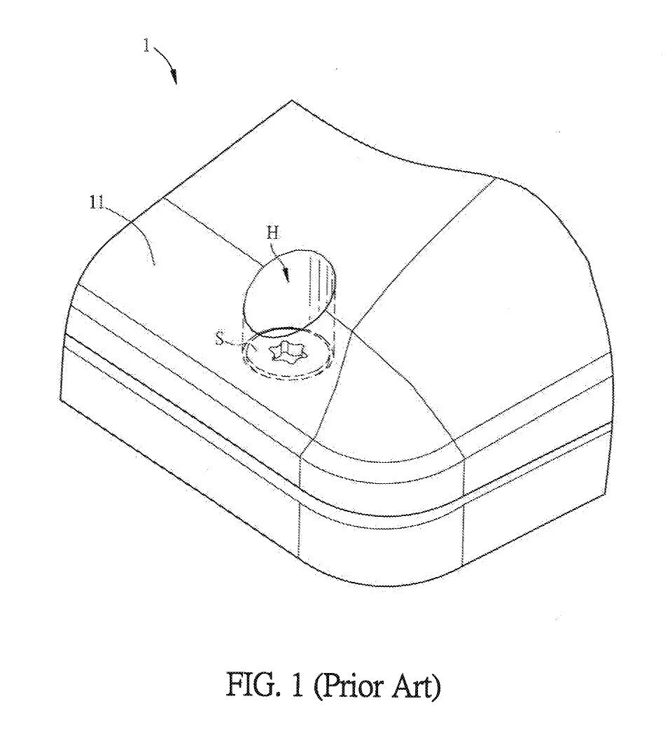

### DETAILED DESCRIPTION OF THE EMBODIMENTS

A casing structure and an electronic device in an embodiment are illustrated. with relating figures, and the same symbols denote the same components.

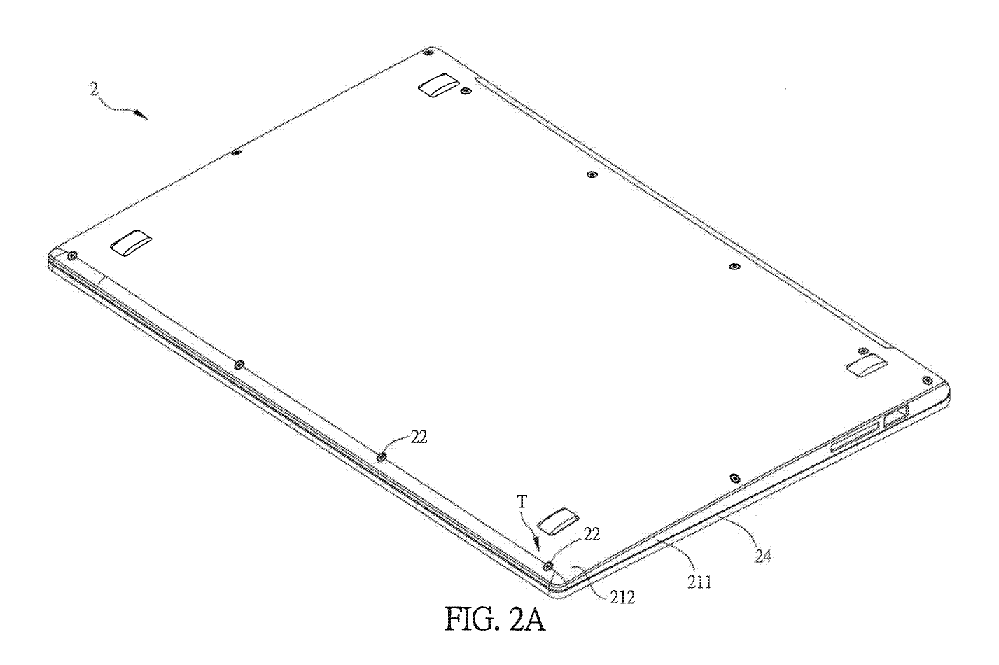

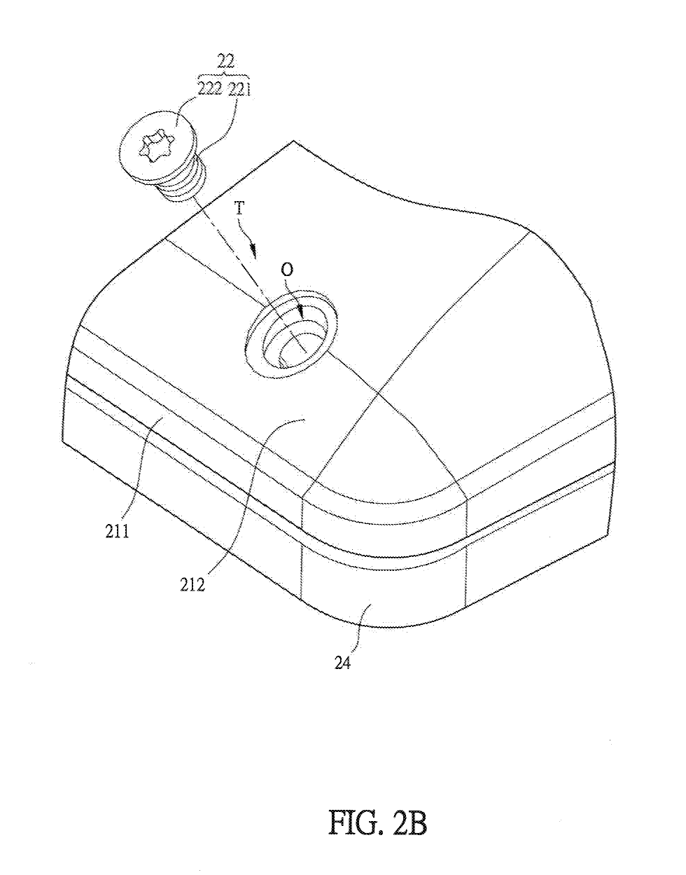

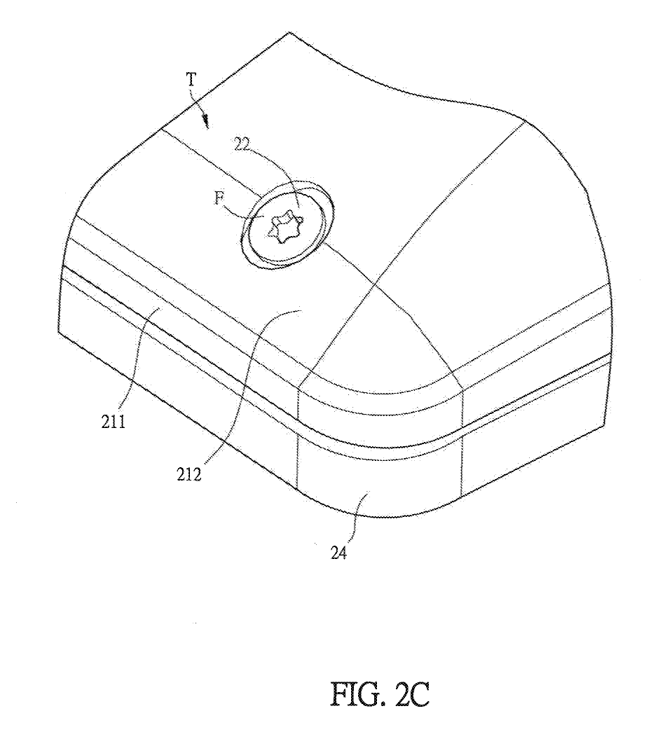

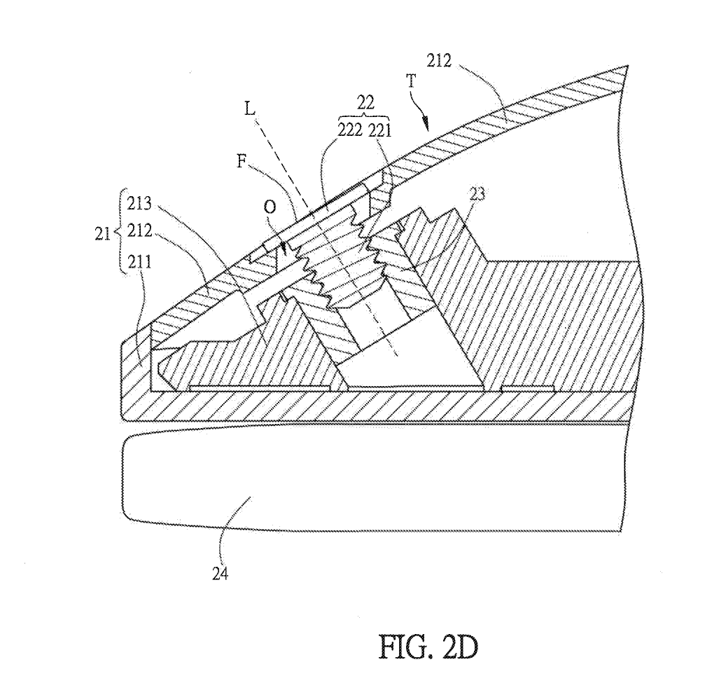

FIG. 2A is a bottom view showing an electronic device 2 in an embodiment, FIG. 2B and FIG. 2C are partial schematic diagrams showing the electronic device 2 in FIG. 2A, and FIG. 2D is a sectional diagram showing the electronic device 2 in FIG. 2C. The electronic device 2 in FIG. 2A to FIG. 2D is put bottom up to illustrate the casing structure 21 more clearly.

The electronic device 2 is a portable electronic device, such as a notebook computer, an ultrabook computer, a tablet computer, a PDA, a GPS, an E-book, an E-dictionary, a multimedia device, a game player, or a mobile communication device. An ultrabook computer is taken as example, which is not limited herein.

The electronic device 2 includes a casing structure 21 and an electronic device body (not shown). The electronic device body may be a motherboard or inner components of the electronic device 2, and the electronic device body is accommodated in the casing structure 21. Since the electronic device 2 in the embodiment is an ultrabook computer (which is at a close state in figures), it further includes a display part 24. The display part 24 may include a display interface (such as a display screen), which is not limited herein. The electronic device may also be a tablet computer or a smart phone, and the display interface of the tablet computer or the smart phone may be disposed in the casing structure 21.

The casing structure 21 includes a first casing 211, a second casing 212, a fixing element 213 and a locking element 22. The electronic device 2 uses multiple locking elements 22 to lock the casing structure 21. The first casing 211 and the second casing 212 are made of metal or plastic, which is not limited herein, and their thickness may be 0.6 mm to 1.0 mm. The first casing 211 is disposed corresponding to the second casing 212. Furthermore, the fixing element 213 may be made of metal or plastic, which is not limited herein. The fixing element 213 is disposed in the first casing 211 and connected to the first casing 211.

In other words, the fixing element 213 and the first casing 211 form an angle which is not equal to 90 degrees. The fixing element 213 and the first casing 211 may be integrally formed, and the fixing element 213 may also be connected to the first casing 211 via a locking element (such as a screw) or other fastening members. In the embodiment, the fixing element 213 is made of plastic, and the first casing 211 and the second casing 212 are made of metal (such as aluminum, aluminum alloy or aluminum magnesium alloy). The fixing element 213 is formed and fixed at the first casing 211 in manufacture.

The second casing 212 has a turning portion T and an opening O. The opening O is formed at the turning portion T, and the fixing element 213 is disposed corresponding to the opening O. The opening O may be shaped in a circle, an ellipse or a strip. The turning portion T may be a curved surface or a slope, and it has a change in angle. In other words, in the embodiment, the bottom of the second casing 212 includes a plate, a curved surface or a slope, and a part of the bottom where the plate begins to change to the curved surface or the slope is the turning portion T. Generally, the turning portion T has a change in angle and is near a side of the electronic device 2. Moreover, a side of the fixing element 213 which is adjacent to the turning portion T is a curved surface or a slope corresponding to the turning portion T.

As shown in FIG. 2D, the locking element 22 includes a fixing part 221. The fixing part 221 of the locking element 22 (such as a screw) passes through the opening O along a normal line L direction of the opening O and is locked with the fixing element 213, so as to combine the second casing 212 and the first casing 211 and accommodate the electronic device body (not shown). The normal line L of the opening O passes through the fixing part 221 of the locking element 22, and is parallel to a long axis direction of the fixing part 221.

Additionally, the locking element 22 further includes an end part 222, and the fixing part 221 is vertical to the end part 222. The fixing part 221 is a pillar of the locking element 22 which has screw threads, and the end part 222 is a part which can be applied force thereon. The locking element 22 is locked to the fixing element 213 by applying force on the end part 222 via a tool.

In the embodiment, the locking element 22 is a screw, and the normal line L is a straight line vertical to a tangent line of a point at the turning portion T (the normal line L at the turning portion T is infinite), and the locking element 22 passes through the opening O along the normal line L direction of the opening O to connect to the fixing element 213. As shown in FIG. 2D, the end part 222 has a surface F corresponding to the curved surface or the slope of the turning portion T.

When the locking element 22 is locked to the fixing element 213, the end part 222 is aligned to the second casing 212, and thus the end part 222 of the locking element 22 and the turning portion T look flat in visual. “Flat” also includes the scope that the end part 222 and the turning portion T have a little fall due to manufacture or material difference. Consequently, the second casing 212 has a flat appearance, which avoids concave holes and makes the appearance of the electronic device 2 integrated, conformity and beautiful.

The casing structure 21 further includes a connecting element 23 fixed on the fixing element 213, and the locking element 22 is connected to the connecting element 23. The connecting element may be a rigid element, such as a buried nail or a screw post, or a flexible element, such as a wall gecko type nail. Thus, the second casing 212 is connected to the first casing 211 by locking the locking element 22 and the connecting element 23 to improve connecting strength. If the locking element 22 is a self-tapping screw, the locking element 22 can be directly locked to the fixing element 213 without the connecting element 23.

If the second casing 212, the locking element 22 or the connecting element 23 is made of metal, electronic elements at a circuit board of the electronic device 2 can be electrically connected to the connecting element 23, the locking element 22 and the second casing 212 via an aluminum foil or cables, and the second casing 212 is used as a ground end.

Although the present invention has been described in considerable detail with reference to certain preferred embodiments thereof, the disclosure is not for limiting the scope. Persons having ordinary skill in the art may make various modifications and changes without departing from the scope. Therefore, the scope of the appended claims should not he limited to the description of the preferred embodiments described above.

What is claimed is:

1. A casing structure, comprising:
a first casing;
a second casing including a turning portion and an opening formed at the turning portion;
a fixing element disposed at the first casing and corresponding to the opening; and
a locking element including an end part and a fixing part, wherein the fixing part passes through the opening along a normal line direction of the opening to fix on the fixing element to make the second casing connected to the first casing and make the end part aligned to the second casing.

2. The casing structure according to claim 1, wherein the turning portion is a curved surface or a slope.

3. The casing structure according to claim 1, wherein the end part has a surface.

4. The casing structure according to claim 3, wherein the surface corresponds to a curved surface or a slope of the turning portion.

5. The casing structure according to claim 1, wherein the casing structure further includes:
a connecting element disposed in the fixing element, wherein the locking element is connected to the connecting element

6. An electronic device comprising:
a casing structure including a first casing, a second casing, a fixing element and a locking element, wherein the second casing has a turning portion and an opening, the opening is formed at the turning portion, the fixing element is disposed in the first casing and corresponds to the opening, and the locking element has an end part and a fixing part; and
an electronic device body,
wherein the fixing part passes through the opening along a normal line direction of the opening to fix on the fixing element to make the second casing connected to the first casing and make the end part aligned to the second casing.

7. The electronic device according to claim 6, wherein the turning portion is a curved surface or a slope.

8. The electronic device according to claim 6, wherein the end part has a surface.

9. The electronic device according to claim 8, wherein the surface corresponds to a curved surface or a slope of the turning portion.

10. The electronic device according to claim 6, wherein the casing structure further includes:
a connecting element disposed in the fixing element, wherein the locking element is connected to the connecting element.
